(19) United States
(12) Patent Application Publication
(10) Pub. No.: US 2019/0062146 A1
(43) Pub. Date: Feb. 28, 2019

(54) MEMS DEVICES AND PROCESSES

(71) Applicant: Cirrus Logic International Semiconductor Ltd., Edinburgh (GB)

(72) Inventors: Tom HANLEY, Edinburgh (GB); Colin Robert JENKINS, Linlithgow (GB)

(73) Assignee: Cirrus Logic International Semiconductor Ltd., Edinburgh (GB)

(21) Appl. No.: 16/106,542

(22) Filed: Aug. 21, 2018

Related U.S. Application Data
(60) Provisional application No. 62/552,576, filed on Aug. 31, 2017.

(30) Foreign Application Priority Data
Sep. 26, 2017 (GB) 1715537.5

(51) Int. Cl. B81B 3/00; B81B 7/00

(52) U.S. Cl. CPC B81B 3/001; B81B 7/0016; B81B 2201/0257; B81B 2203/0315; B81B 2203/0338; B81B 2203/0361; B81B 2203/0127

(57) ABSTRACT

The application describes a MEMS transducer comprising a membrane which comprises an active membrane region and a substrate having a cavity. An upper surface of the substrate comprises an overlap region which underlies the membrane. A first portion of the overlap region is provided with at least one recess. The at least one recess does not intersect an edge of the cavity.

### TECHNICAL FIELD

The embodiments of the present invention relate to micro-electro-mechanical system (MEMS) devices and processes, and in particular to a MEMS device and process relating to a transducer, for example a capacitive microphone.

### BACKGROUND

Various MEMS devices are becoming increasingly popular. MEMS transducers, and especially MEMS capacitive microphones, are increasingly being used in portable electronic devices such as mobile telephones and portable computing devices.

Microphone devices formed using MEMS fabrication processes typically comprise one or more moveable membranes and a static backplate, with a respective electrode deposited on the membrane(s) and backplate, wherein one electrode is used for read-out/drive and the other is used for biasing, and wherein a substrate supports at least the membrane(s) and typically the backplate also. In the case of MEMS pressure sensors and microphones the read out is usually accomplished by measuring the capacitance between the membrane and backplate electrodes. In the case of transducers, the device is driven, i.e. biased, by a potential difference provided across the membrane and backplate electrodes.

FIGS. 1a and 1b show a schematic diagram and a perspective view, respectively, of a known capacitive MEMS microphone device 100. The capacitive microphone device 100 comprises a membrane layer 101 which forms a flexible membrane which is free to move in response to pressure differences generated by sound waves. A first electrode 103 is mechanically coupled to the flexible membrane, and together they form a first capacitive plate of the capacitive microphone device. A second electrode 102 is mechanically coupled to a generally rigid structural layer or backplate 104, which together form a second capacitive plate of the capacitive microphone device. In the example shown in FIG. 1a the second electrode 102 is embedded within the backplate structure 104.

The capacitive microphone is formed on a substrate 105, for example a silicon wafer, which may have upper and lower oxide layers 106, 107 formed thereon. A cavity or through-hole 108 in the substrate and in any overlying layers (hereinafter also referred to as a substrate cavity) is provided below the membrane, and may be formed for example using a “back-etch” through the substrate 105. The substrate cavity 108 connects to a first cavity 109 located directly below the membrane. These cavities 108 and 109 may collectively provide an acoustic volume thus allowing movement of the membrane in response to an acoustic stimulus. Interposed between the first and second electrodes 102 and 103 is a second cavity 110.

A plurality of holes, hereinafter referred to as bleed holes 111, connect the first cavity 109 and the second cavity 110.

A further plurality of holes, hereinafter referred to as acoustic holes 112, are arranged in the back-plate 104 so as to allow free movement of air molecules through the back plate, such that the second cavity 110 forms part of an acoustic volume with a space on the other side of the back-plate. The membrane 101 is thus supported between two volumes, one volume comprising cavities 109 and substrate cavity 108 and another volume comprising cavity 110 and any space above the back-plate. These volumes are sized such that the membrane can move in response to the sound waves entering via one of these volumes. Typically the volume through which incident sound waves reach the membrane is termed the “front volume” with the other volume, which may be substantially sealed, being referred to as a “back volume”.

In some applications the backplate may be arranged in the front volume, so that incident sound reaches the membrane via the acoustic holes 112 in the backplate 104. In such a case the substrate cavity 108 may be sized to provide at least a significant part of a suitable back-volume.

In other applications, the microphone may be arranged so that sound may be received via the substrate cavity 108 in use, i.e. the substrate cavity forms part of an acoustic channel to the membrane and part of the front volume. In such applications the backplate 104 forms part of the back-volume which is typically enclosed by some other structure, such as a suitable package.

It should also be noted that whilst FIG. 1a shows the backplate 104 being supported on the opposite side of the membrane to the substrate 105, arrangements are known where the backplate 104 is formed closest to the substrate with the membrane layer 101 supported above it.

In use, in response to a sound wave corresponding to a pressure wave incident on the microphone, the membrane is deformed slightly from its equilibrium position. The distance between the lower electrode 103 and the upper electrode 102 is correspondingly altered, giving rise to a change in capacitance between the two electrodes that is subsequently detected by electronic circuitry (not shown). The bleed holes allow the pressure in the first and second cavities to equalise over a relatively long timescale (in acoustic frequency terms) which reduces the effect of low frequency pressure variations, e.g. arising from temperature variations and the like, but without significantly impacting on sensitivity at the desired acoustic frequencies.

One skilled in the art will appreciate that MEMS transducers are typically formed on a wafer before being singulated. Increasing it is proposed that at least some electronic circuitry, e.g. for read-out and/or drive of the transducer, is also provided as part of an integrated circuit with the transducer. For example a MEMS microphone may be formed as an integrated circuit with at least some amplifier circuitry and/or some circuitry for biasing the microphone. The footprint of the area required for the transducer and any circuitry will determine how many devices can be formed on a given wafer and thus impact on the cost of the MEMS device. There is therefore a general desire to reduce the footprint required for fabrication of a MEMS device on a wafer.

In addition to be suitable for use in portable electronic devices such transducers should be able to survive the expected handling and use of the portable device, which may include the device being accidentally dropped.

If a device such as a mobile telephone is subject to a fall, this can result not only in a mechanical shock due to impact but also a high pressure impulse incident on a MEMS transducer. For example, a mobile telephone may have a sound port for a MEMS microphone on one face of the device. If the device falls onto that face, some air may be compressed by the falling device and forced into the sound port. This may result in a high pressure impulse incident on the transducer. It has been found that in conventional MEMS transducers high pressure impulses can potentially lead to damage of the transducer.

FIG. 2 illustrates a cross-sectional view through a typical transducer structure. The transducer structure comprises a membrane 101 which is moveable during use in relation to a rigid backplate 104. The membrane 101 and backplate 104 are supported by a substrate 105, the substrate 105 comprising a cavity or though-hole 108. Electrodes and other features are not shown in FIG. 2 for clarity purposes.

Referring to FIG. 3, during movement of the membrane 101 during use, and in particular during high input acoustic pressure, or extreme conditions such as a mobile device being dropped, it is possible that the membrane 101 makes contact with the substrate 105 which provides support for the membrane. For example, the membrane 101 can make contact with a peripheral edge of the substrate 105 that forms the cavity within the substrate, as illustrated by the arrow 30. This can result in the membrane becoming damaged.

This problem may be particularly apparent in transducer configurations—such as is illustrated in FIG. 4—wherein an active or flexible part of a generally square shaped membrane layer comprises an active central region 301 and a plurality of support arms 303 which extend laterally from the active central region for supporting the active central region of the membrane. A plurality of slits 304 are etched through the layer of the membrane material to form a boundary between the active region of the membrane and a plurality of inactive regions 302. In this case it will be appreciated that a boundary of the active membrane that is defined by one of the slits 304—in other words an unbound edge of the active membrane region—may be particularly vulnerable in the event that the active membrane makes contact with the edge 308 of the substrate cavity.

Furthermore, the occurrence of membrane stiction—whereby the membrane becomes permanently or temporarily adhered to the substrate—may also be observed following a high pressure event which causes the membrane to make contact with the substrate. This is illustrated in FIGS. 5A and 5B. Specifically, in FIG. 5A the membrane 101 is suspended freely with respect to the substrate 105. However, in FIG. 5B the membrane 101 has become adhered to the upper surface of the substrate 105 following e.g. a high pressure event. It will be appreciated that stiction arises when e.g. atomic-level attractive forces and/or capillary forces and/or chemical bonding arising between the membrane and the substrate exceed restoring forces e.g. arising from the elasticity of the membrane which act to restore the membrane to an equilibrium position. Membrane stiction may significantly degrade the performance of the transducer or may even result in the failure of the transducer.

Aspects described herein are generally concerned with improving the efficiency and/or performance of a transducer structure. Aspects described herein are particularly concerned with alleviating problems associated with stiction of the membrane to the substrate. Further aspects may be additionally or alternatively concerned with mitigating the risk of membrane damage during e.g. a high pressure impulse.

According to an example embodiment of a first aspect there is provided a MEMS transducer comprising: a membrane comprising an active membrane region; a substrate having a cavity; wherein an upper surface of the substrate comprises an overlap region which underlies the membrane, wherein a first portion of the overlap region is provided with at least one recess, and wherein the at least one recess does not intersect an edge of the cavity.

According to an example embodiment of a second aspect there is provided a MEMS transducer comprising a substrate, the substrate comprising a cavity which extends through the substrate from an upper surface of the substrate to a lower surface of the substrate wherein the upper surface of the substrate is provided with at least one longitudinal channel, wherein a longitudinal axis of the at least one channel extends in a direction parallel to a notional line drawn tangentially to an edge of the cavity.

According to an example embodiment of a third aspect there is provided a MEMS transducer comprising: a membrane, the membrane being provided with at least one slit which defines a flexible portion of the membrane; a substrate having a cavity; wherein the membrane overlies the substrate and wherein at least one recess is formed in an upper surface of the substrate which underlies the at least one slit. Thus, at least one portion of the upper surface of the substrate is provided with a plurality of recesses. A recess can be considered to be a region where the upper surface of the substrate is lower than an adjacent upper surface region of the substrate. Thus, the plurality of recesses may define a series of lower regions which are provided between adjacent higher regions in the upper surface of the substrate.

The active membrane region may comprise a plurality of bound edges and a plurality of unbound edges. The active membrane region may comprise a central region and a plurality of support arms which extend laterally from the central region. The first portion of the overlap region may underlie a first unbound edge of the active membrane. The first portion of the overlap region may be provided between a second portion of the overlap region and a third portion of the overlap region. The second and third portions of the overlap region may each underlie one of the plurality of support arms of the membrane. At least one recess may be disposed between the second and third portion of the overlap region. At least a portion of the at least one recess may extend between the second portion of the overlap region and the third portion of the overlap region.

The recess may comprise a channel formed in the upper surface of the substrate. The channel may be generally longitudinal and comprise a longitudinal axis. At least a portion of the longitudinal axis of the channel may extend in a direction that is substantially parallel to the edge of the substrate cavity. At least a portion of the longitudinal axis of the channel may extend in a direction that is substantially parallel to an unbound edge of the active membrane, or to a perimeter of the membrane. The longitudinal axis of the channel may not intersect the edge of the cavity. The channel may exhibit a substantially square or rectangular cross section.

Features of any given aspect may be combined with the features of any other aspect and the various features described herein may be implemented in any combination in a given embodiment.

Associated methods of fabricating a MEMS transducer are provided for each of the above aspects and examples described herein.

### BRIEF DESCRIPTION OF THE DRAWINGS

For a better understanding of the present invention, and to show how it may be put into effect, reference will now be made, by way of example to the accompanying drawings, in which:

FIGS. 1a and 1b illustrate sectional and perspective views of a known MEMS microphone structure;

FIG. 2 illustrates a cross-sectional view through a MEMS transducer structure;

FIG. 3 illustrates deflection of a membrane in the MEMS transducer structure of FIG. 2;

FIG. 4 illustrates a plan view of a MEMS transducer structure;

FIGS. 5A and 5B illustrates the problem of membrane stiction;

FIGS. 6A and 6B illustrate a MEMS transducer according to a first example;

FIGS. 7A and 7B illustrate recesses provided in a portion of the upper surface of a substrate according to one example;

FIG. 7C illustrates a further example of recesses provided in a portion of the upper surface of a substrate;

FIGS. 8A and 8B illustrate a previously proposed design wherein the overlap portion of the substrate is provided with a plurality of bumps;

FIG. 9 illustrates a partial perspective view and cross section view of the example shown in FIG. 7A;

FIGS. 10A and 10B illustrate the relative contact between a membrane and a substrate;

FIG. 11 illustrates a plan view of the membrane layer of a MEMS transducer according to a further example;

FIG. 12 illustrates a plan view of the upper layer of the substrate of the MEMS transducer corresponding to FIG. 11;

FIG. 13 illustrates the upper layer of the substrate of a MEMS transducer according to a further example; and

FIG. 14 illustrates the upper layer of the substrate of a MEMS transducer according to a further example.

### DETAILED DESCRIPTION

It will be appreciated that, in the membrane layer of a MEMS transducer, a material is said to be under stress when its atoms are displaced from their equilibrium positions due to the action of a force. Thus, a force that increases or decreases the interatomic distance between the atoms of the membrane layer gives rise to stress within the membrane. For example, the membrane layer may exhibits a non-zero inherent, or intrinsic, residual stress when at equilibrium (i.e. when no or negligible differential pressure arises across the membrane). Furthermore, stresses can arise in the membrane layer e.g. due to the way in which the membrane is supported in a fixed relation to the substrate or due to an acoustic pressure wave incident on the membrane.

MEMS transducers according to the present invention are intended to respond to the acoustic pressure waves which give rise to transient stress waves on the membrane surface. Thus, it will be appreciated that the stress concentrations that may arise within a membrane layer, both when at equilibrium and when moving during use, may potentially have a detrimental impact on the performance of a transducer.

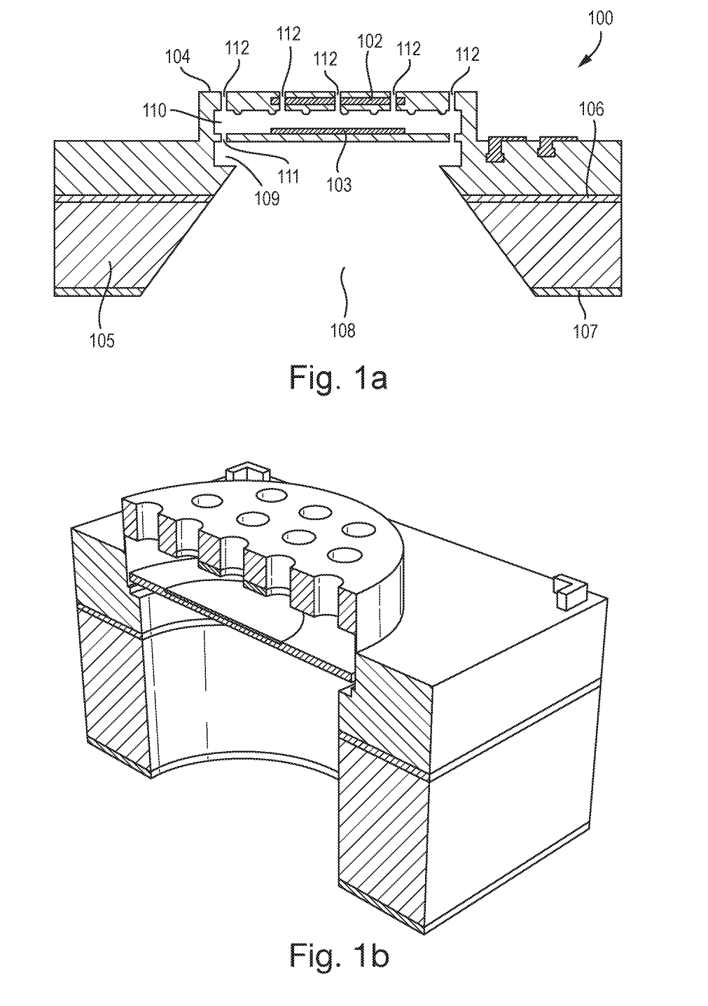

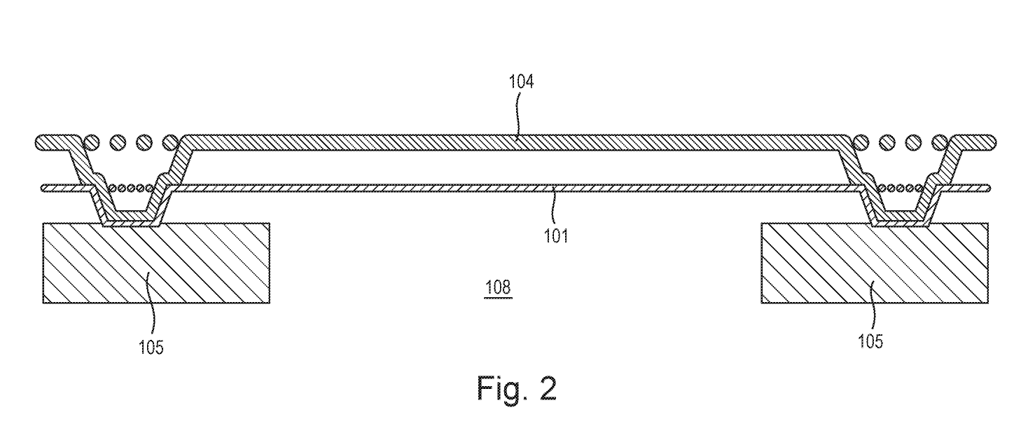

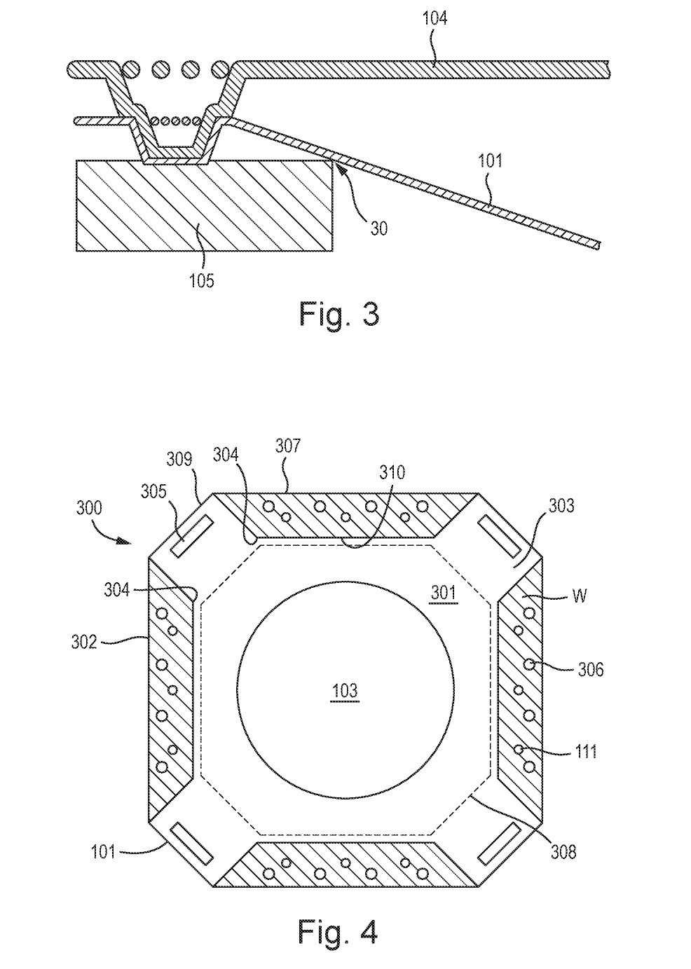

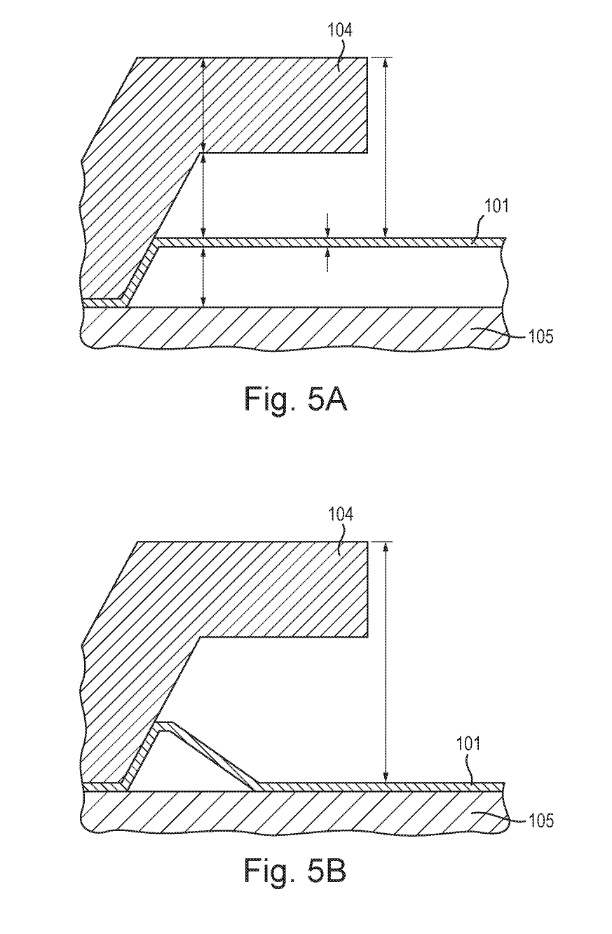

In transducers such as described above in relation to FIGS. 1a, 1b, 2 and 3, the membrane layer may be formed from a material such as silicon nitride and may be deposited to have residual stress inherent in the membrane at equilibrium. The membrane may be formed so as to be supported around substantially the whole of its periphery. The membrane can therefore be thought of as being under tension, akin to a drum skin stretched over a frame. To provide uniform behaviour and even stress distribution the membrane is thus typically formed as a generally circular structure.

For instance to form the transducer structure illustrated in FIG. 1a, one or more base layers may be formed on the substrate 105 and then a layer of sacrificial material may be deposited and patterned to form a generally circular shape. The sacrificial material serves to define the space that will form cavity 109. One or more layers may then be deposited on the sacrificial material to form the membrane 101. The bleed holes 111 may be formed in the membrane layer along with any vent structures such as described with reference to FIG. 1a or 1b. A further sacrificial material layer may then be deposited on top of the membrane and patterned to define cavity 110. The back plate layers can then deposited. To form the substrate cavity 108 a back etch may be performed. To ensure that it is the sacrificial material that defines cavity 109 and not the bulk back etch (which would be less accurate) it is preferably ensured that the opening of the substrate cavity is smaller than cavity 109 and located within the area of the cavity 109. The sacrificial material can then be removed to leave cavities 109 and 110 and release the membrane. The membrane layer(s) thus extend into the side wall structure that also supports the back-plate. The flexible membrane itself is supported and constrained on all sides and is substantially circular in shape.

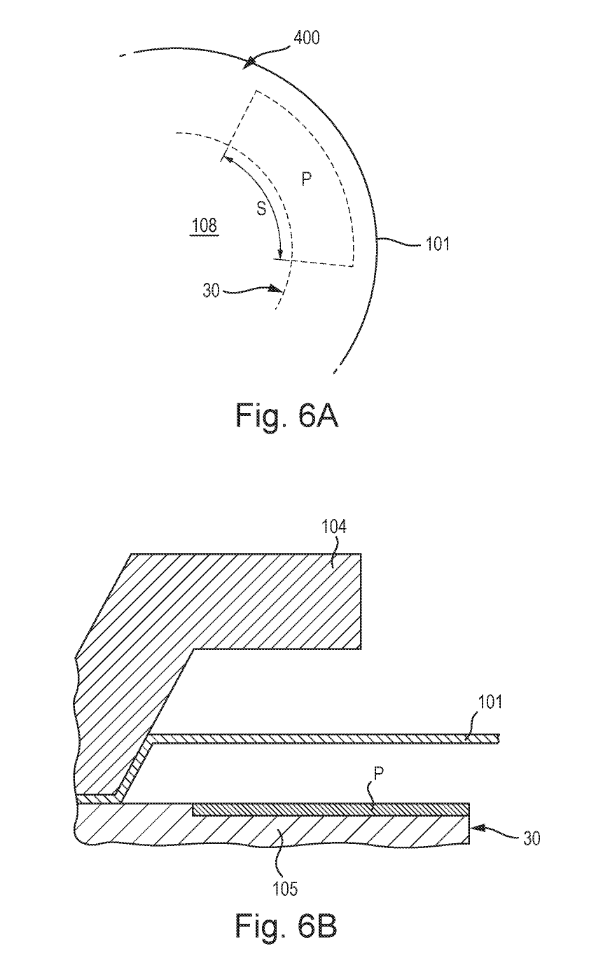

FIGS. 6A and 6B illustrate a MEMS transducer structure according to a first example. Specifically, FIG. 6A shows a part of a plan view of a flexible membrane 101 of the transducer structure whilst FIG. 6B illustrates the transducer structure in cross section. The peripheral edge 30 of the underlying cavity 108 within the substrate 105 which supports the membrane is indicated in dotted lines. It will be appreciated that the region laterally outside the cavity i.e. between the dotted line and the perimeter of the flexible membrane 101, defines an overlap region 400 of the underlying substrate. The overlap region 400 can be considered to be a region of the substrate where the membrane 101 overlies the substrate 105. A first area or portion P of the overlap region of the substrate is defined which extends laterally outward from a segment S of the substrate cavity edge. In this example the first portion P does not extend all the way to the perimeter of the flexible membrane.

According to the present examples, the portion P of the substrate is provided with a plurality of recesses (not shown) in the upper surface thereof. According to one or more examples, the recesses do not intersect the cavity edge 30. Thus, the floor of the recess i.e. the region where the upper surface of the substrate is lower than adjacent upper surface regions, does not intersect the cavity edge.

From consideration of FIG. 6B it can be appreciated that if the membrane deflects sufficiently to come into contact with the underlying substrate, then the membrane will make contact with the portion P of the substrate that is provided with a plurality of recesses.

It will be appreciated that the stiction energy or stiction force or adhesive force arising between the membrane and the substrate is linearly proportional to the contact area between the membrane and the substrate. Thus, the provision of a plurality of recesses in the upper surface of the substrate effectively reduces the contact area that arises between the membrane and the substrate, since the membrane will preferably only make contact with the raised surface areas of the upper surface of the substrate in the region P. Thus, an advantage of such a configuration is that the likelihood of the membrane becoming adhered to the upper surface of the substrate in the event that the membrane makes contact with the underlying substrate is reduced.

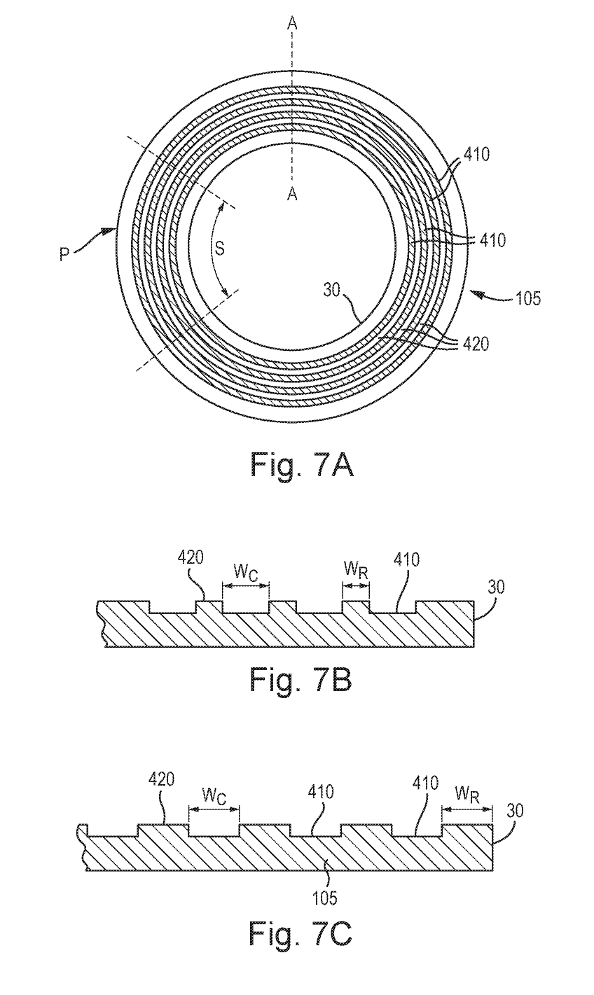

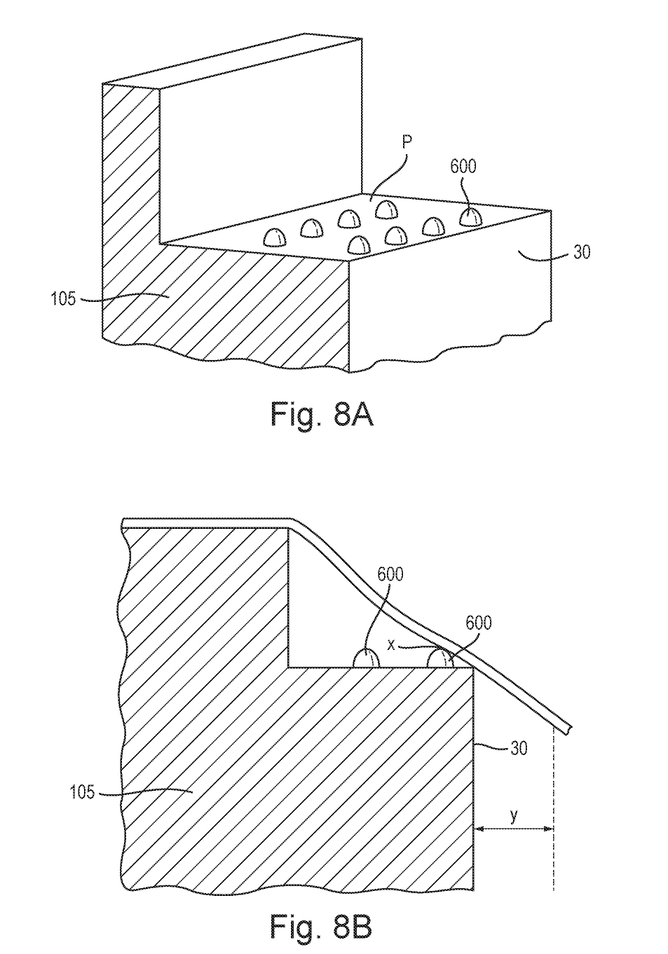

FIG. 7A illustrates a plan view of the upper surface of the substrate according to one example wherein the upper surface of the substrate comprises a plurality of recesses 410. In this example, the recesses comprise a plurality of channels which are defined in the upper surface of the substrate. Thus, according to the illustration shown in FIG. 7A, the recesses 410 are indicated by the shaded regions which extend between adjacent ridges 420.

It will be appreciated that the recesses may be formed by removing material from the upper surface of the substrate to thereby form a plurality of lower regions forming the recesses 410 that are provided between adjacent higher regions, or ridges, 420. In this case the upper surface of the ridges will be substantially coplanar with the upper surface of the rest of the substrate. Alternatively, the recesses may be formed by depositing additional material onto the surface of the substrate to form a series of ridges which extend within the overlap region P of the substrate. The recesses will thus be defined between the ridges and are configured so as to not intersect the edge of the cavity. In this case the upper surface of the recesses or lower regions 410 will be substantially coplanar with the upper surface of the rest of the substrate.

FIG. 7B shows an expanded, cross-sectional view of the example shown in FIG. 7A taken along the line A-A. The recesses in this example comprise a series of channels having a substantially rectangular cross-section. In this example the width of the channel We (wherein the width is defined in a direction substantially orthogonal to the edge of the cavity) may be around 2 μm, whilst the width of the ridge may be around 1 μm. Thus, the channel to ridge ratio is around 2:1 in this example. The depth of the channel Dc is around 120 nm.

In the event of the membrane making contact with the substrate, the initial impact area of the substrate—in other words the available contact area that will arise in the first instance of contact between the membrane and the substrate—may be decisive in determining the likelihood of the membrane experiencing damage and/or failure. The smaller the initial impact area, the higher the local stress generated in the membrane and hence the likelihood of membrane damage/failure is increased.

Referring now to FIG. 8A which illustrates a part of a perspective view of a previously proposed design according to which a plurality of raised bumps 600 are provided on the substrate ledge—i.e. on a portion P of the overlap region between the edge of the cavity and a perimeter of the flexible membrane where the membrane overlies the upper surface of the substrate. It can be appreciated from consideration of FIG. 8B—which illustrates a cross-section through configuration illustrated in FIG. 8A—that if the initial contact between the membrane and the substrate is between one, or even several, of the bumps 600 which project from the upper surface of the substrate, the initial impact area will be relatively small and, thus, that relatively high regions of stress will arise within the membrane layer.

Thus, whilst it is desirable to reduce the overall contact area that arises between the substrate and the membrane in circumstances of e.g. a high pressure event, it is also desirable to maintain a sufficiently large initial impact area of the substrate, particularly at the point where the edge of the cavity may contact the membrane layer, in order to mitigate stress concentrations arising within the membrane on contact with the substrate.

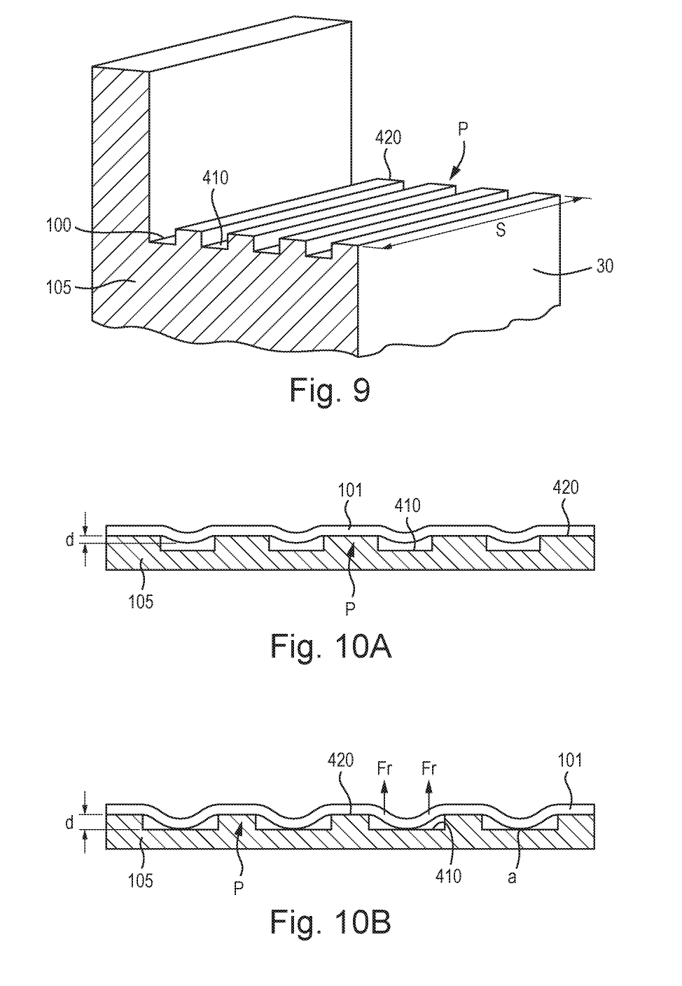

FIG. 9 illustrates a partial perspective view of the example shown in FIG. 7A. It will be seen that the provision of a plurality of recesses which each extend within the overlap region of the substrate is potentially advantageous, since the potential initial impact area of the edge of the cavity with the flexible membrane is defined by a continuous line or region of contact that extends the length of the segment S of the portion P. The line of contact therefore does not have a surface that varies in height at the edge of the cavity. Thus, as a consequence of the recesses extending in a direction that does not intersect the cavity edge, the stress resulting from contact of the membrane with the edge of the cavity is effectively distributed along the length of the segment S. Nonetheless, as is shown in this Figure, the height of the upper surface of the substrate varies from a higher surface to a lower surface from the edge of the cavity 30 towards the perimeter of the flexible membrane 100. Thus, the contact area of the membrane and the substrate is significantly reduced. Examples described herein may therefore provide the advantage that the stresses generated in the membrane as a result of the membrane making contact with the edge of the cavity are distributed, and/or reduced, whilst at the same time the stiction forces arising between the flexible membrane and the substrate are also reduced.

It will be appreciated that the geometry and/or dimensions of the recesses may be selected in order to ensure that, for a given transducer design, the potential adhesive forces that arise in the event of the membrane and substrate coming into contact do not exceed the restoring forces. The adhesive forces may be at least partly determined by the likely or potential contact area between the membrane and the upper surface of the substrate. Moreover, the potential contact area will depend on the extent to which the membrane may make contact with the upper surface of the recessed regions, which is determined by the geometry—e.g. shape—and dimensions of the recesses e.g. the depth of the recesses and/or the recess to ridge ratio. The restoring forces may at least partially depend on the gradient of the remaining unstuck membrane.

For example, FIG. 7C shows a cross-sectional view taken along a line which extends laterally outward from the edge of the cavity to the perimeter of the transducer of a further example in which the channel to ridge ratio is around 1:1. Examples comprising a substrate having a portion provided with a plurality of recesses are also envisaged which exhibit a 3:1 or 4:1 ratio. It will be appreciated that higher ratios of eg. up to 10:1 or higher may be manufactured, and that the limit of the channel formation is influenced by the process control of said formation. However, it will be appreciated that if the width of the channel becomes too great, the likelihood that the membrane will dip into the recess and potentially make contact with the lower surface of the recesses will increase. This is illustrated in FIGS. 10A and 10B which show the relative contact between the membrane and the substrate. Thus, in FIG. 10A the channel to ridge ratio is around 1:1 and the recesses exhibit a depth of d. In the event of contact between the membrane and the substrate, the membrane does not come into contact with the upper surface of the recessed regions of the substrate. However, as shown in FIG. 10B wherein the channel to ridge ratio is around 2:1, in the event of contact between the membrane and the substrate, the membrane does make contact with the upper surface of the recessed regions of the substrate, thus generating an additional contact area a.

In this event, the adhesive forces arising between the membrane and the upper surface of the recesses may become sufficient to exceed the local restoring force Fr of the membrane. The depth of the recess also partly determines if the membrane can make contact with the upper surface of the recessed regions. Preferably, the dimensions of the recesses are selected such that the membrane makes limited contact with the upper surface of the recesses. In this case, the overall contact area between the membrane and the upper surface of the substrate is reduced, thereby mitigating the risk of stiction. Alternatively, the dimensions of the recesses may be selected such that if the membrane does make contact with the upper surfaces of the recesses, the local restoring force is still greater than the total adhesive force. Thus it is possible for the channel width Wc to be defined in design such that any contact in the recessed regions generates a force less than the local restoring for Fr. This sets an upper limit on Wc.

Whilst circular membranes as illustrated in FIGS. 6A-6B and 7A-7C produce good device properties, the use of circular membranes tends to result in some inefficiency during fabrication in the use of the silicon wafer. For various reasons it is most usual and/or cost effective to process areas of silicon in generally rectangular blocks of area. Thus the area on a silicon wafer that is designated for the MEMS transducer is typically generally square or rectangular in shape. This area needs to be large enough to encompass the generally circular transducer structure. This tends to be inefficient in terms of use of the silicon wafer as the corner regions of this designated transducer area are effectively unused. This limits the number of transducer structures and circuits that can be fabricated on a given wafer. It would of course be possible to fit more transducers on a wafer by reducing the size of the transducer but this would have an impact on resulting sensitivity and thus is undesirable.

According to further examples described herein the transducer is based on a design that more efficiency utilises a generally rectangular or square area such as that shown in FIG. 4. This design requires less area for a given transducer sensitivity than an equivalent circular design.

FIG. 4 illustrates an example of a transducer 300, whereby instead of having a circular membrane a different membrane shape is used. FIG. 4 illustrates the transducer membrane 101 and thus represents a section through the transducer although the backplate may have substantially the same shape. The membrane is not substantially circular and instead, in this example, has a polygon shape. In general the membrane has a shape that would substantially fill a square area defined by the perimeter of the membrane. In other words if one were to consider the smallest possible square area that would completely contain the membrane 101 then the membrane would cover a large proportion of such an area, for example the membrane may cover at least 90% of such a square area. It will be appreciated that for a circular membrane of diameter D the smallest such square area would have a side D. The area of the circle (π·D²/4) would thus cover about 78% of the area of such a square (D²).

The whole area illustrated in FIG. 4 is provided with a layer of membrane material. However in the example illustrated in FIG. 4 the layer of membrane material is divided into a first membrane region 301, which will be referred to herein as an active membrane region or just as active membrane, and a plurality of second regions 302 which will be referred to as inactive membrane regions. The active membrane is the membrane which will be used for sensing acoustic pressure variation, and on which an electrode will usually be provided. The inactive membrane regions 302 are illustrated by the shaded regions of the membrane layer in FIG. 4, with the unshaded area corresponding to the active membrane 301.

Conveniently during manufacture a continuous layer of membrane material—i.e. the membrane layer—may be deposited and pinned/supported/fixed at the perimeter. Slits 304 may then be etched through the membrane material to form the active and inactive regions of the membrane layer. In this particular example, the membrane layer is pinned, or fixed, along eight sides. Four slits (channels or gaps) 304 are provided in the membrane layer and separate the active and inactive regions of the membrane layer, where in this example there is one active membrane 301 region and four inactive membrane regions 302. The active membrane region can therefore be considered to be provided with a plurality of unbound edges 310 which are free to move, and a plurality of bound edges 309 which are fixed. In this example, the active membrane region comprises four bound edges and four unbound edges, where each unbound edge is situated so as to overlie the upper layer of the substrate. However, it will be appreciated that the unbound edge may instead at least partially overlie the cavity so that only a portion of the bound edge overlies the upper layer of the substrate. For example, in some configurations the perimeter of the active membrane may at least partially terminate in a region overlying the cavity, so that when the greatest displacement of the membrane occurs, the active portion of the membrane will not contact the substrate.

The active membrane comprises a central area, e.g. where the membrane electrode 103 will be located, which is supported by a plurality of arms 303. In some embodiments the arms may be distributed substantially evenly around the periphery of the membrane. A generally even distribution of arms may help avoid unwanted stress concentration. In the example illustrated in FIG. 4 there are four arms 303, but it will be appreciated that there may be more or fewer arms in other embodiments, although preferably there will be at least three arms. Each arm 303 of the active membrane region 301 may comprise at least one mount 305 for supporting the membrane layer of the active region 301 with respect to the substrate and also possibly a backplate. There may also be mounts 306 within the inactive membrane regions for supporting the inactive membrane region.

The mounts 305 and 306 may take various forms. For instance the mount could comprise a sidewall of the transducer structure and the membrane layer may extend into the sidewall. In some examples however the mount may be a region where the membrane material makes contact with the substrate or a support structure that rises from the substrate. The mount may also comprise an area where the support structure for the backplate makes contact with the membrane. The membrane at the mount is thus effectively held in place and prevented from any substantial movement with respect to the substrate and/or backplate. The bound edges of the active membrane are thus defined with respect to the mounts which support the active membrane at the boundary of the support arms, at each of the four “corners” of the active membrane. The mounts can be considered to constrain or bound the edge of the membrane so that it is fixed and substantially unable to deflect.

The material of the membrane layer can thus be deposited with intrinsic stress as described previously. The plurality of arms of the active region 301 all radiate generally away from the centre of the active membrane and thus can act to keep the membrane effectively in tension. As mentioned the arms may be evenly spaced around the active membrane. In addition the mounting points for the active membrane 301, e.g. mounts 305 may all be substantially equidistant from the centre of the active membrane—even with a generally square membrane layer. This is possible because the membrane material at the ‘sides’ of the square arrangement have been separated into inactive membrane regions that are not directly connected to the active membrane region. This arrangement thus means that the distribution of stress in the central portion of the active membrane is generally even, both at equilibrium and when the active membrane is deflected by an incident pressure stimulus, with most of any stress modulation being instead in the arms. The active membrane will thus behave in a similar way to a circular membrane which is constrained all around its periphery. This would not be the case were a square membrane, or the polygon membrane illustrated in FIG. 4, bounded on all sides.

Such a design is potentially advantageous as it provides an active membrane area that has a similar response to a circular membrane with a radius equal to the distance between the centre of the active membrane and the mounts 305 of the arms. However to fabricate such a corresponding circular membrane transducer would require a larger rectangular area of the substrate. By using a design such as illustrated in FIG. 4 the area required for the transducer on a wafer may therefore be reduced compared to a circular membrane of similar performance.

In previous transducer configurations similar to that illustrated in FIG. 4, it was typical for the unbound edge of the active or flexible portion of the membrane to extend at least partially over the substrate cavity. Thus, in this arrangement, a large proportion of the unbound edge did not overlap the upper surface of the substrate. Thus, the risk of stiction between the unbound edges of the membrane and the upper surface of the substrate was relatively low, and/or confined to a relatively small portion of the unbound edge at or near the or each support arm.

However, in recent designs, there has been a tendency for the cross sectional area of the substrate cavity to be reduced. This may be to improve the robustness of the MEMS transducer, for example. Accordingly, and in particular when a smaller cavity size is used in conjunction with a flexible membrane region that is supported or pinned at a number of discrete perimeter locations, such that the flexible membrane region comprises a plurality of bound and unbound edges, it is more likely that an unbound edge of the active membrane—in particular the portion of the unbound edge that extends between the support arms of the active membrane region—at least partially overlies the upper surface of the substrate. This means that significant stiction forces may act on the active membrane in the regions of the unbound edges. It is therefore necessary to seek to alleviate the risk of stiction at the regions in the vicinity of the unbound edges of the active membrane.

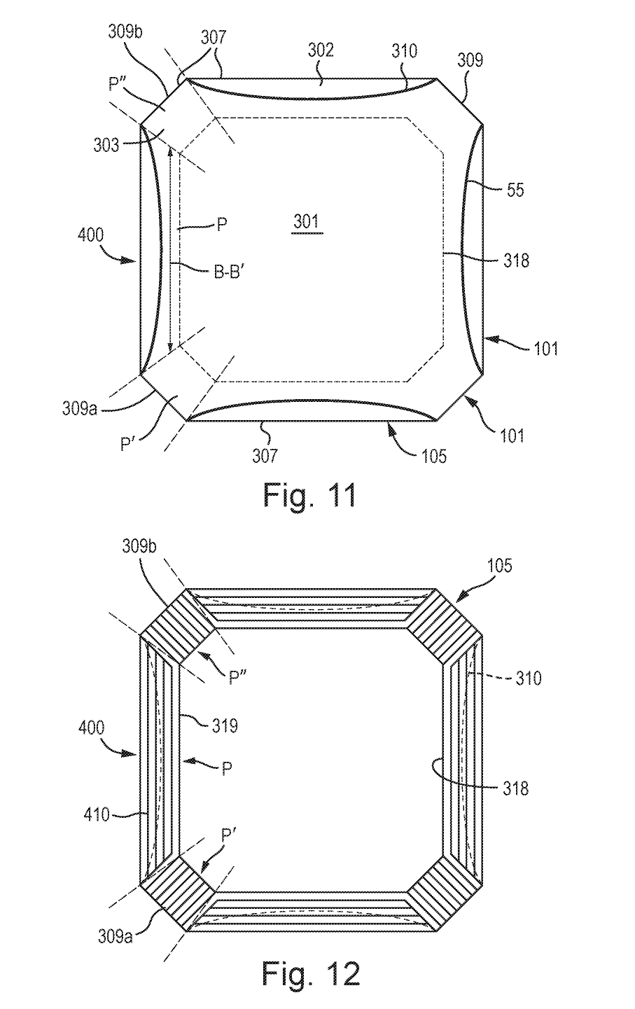

FIG. 11 illustrates a MEMS transducer structure according to a further example of the present invention. Specifically, FIG. 11 shows a plan view of a membrane layer 101 of the transducer structure. The membrane layer is similar to that of FIG. 4 having an active membrane region comprising a centre region 301 and a plurality of supporting arms 303 in addition to a plurality of inactive membrane regions 302 which are separated from the active membrane by slits and define an unbound edge 310 of the membrane. The peripheral edge 318 of the underlying cavity within the substrate is shown in dotted lines. The region laterally outside the cavity i.e. between the dotted line and the perimeter of the flexible membrane 307 defines an overlap region 400 of the underlying substrate. The overlap region 400 can be considered to be a region of the substrate where the membrane overlies the substrate 105.

The overlap region 400 comprises a first portion P which underlies one of the unbound edges 310 of the active membrane. In this example embodiment, the first portion P is located between two regions—namely a second portion of the overlap region P′ and a third portion of the overlap region P″—which underlie the support arms of the active membrane region. According to one or more examples, the upper surface of the first portion P of the substrate is provided with a plurality of recesses (not shown). Thus, the recesses are provided in a region between the second P′ and third P″ portions of the overlap region which are in the vicinity of first 309a and second 309b bound edges of the active membrane region.

The recesses may take a variety of forms. For example, the recesses may comprise a plurality of channels similar to those illustrated in FIGS. 7A, 7B and 7C.

From consideration of FIG. 11 it can be appreciated that if the active membrane deflects sufficiently to come into contact with the underlying substrate, then the membrane will come into contact with the portion P of the upper surface of the substrate that is provided with a plurality of recesses. An advantage of such a configuration is that the likelihood of the membrane becoming adhered to the upper surface of the substrate in the event that the membrane makes contact with the underlying substrate, is reduced. As discussed above, the stiction force or adhesive force arising between the membrane and the substrate is linearly proportional to the contact area between the membrane and the substrate. Thus, the provision of a plurality of recesses in the upper surface of the substrate effectively reduces the contact area between the membrane and the substrate, since the membrane will make limited or no contact with the upper surface of the substrate in the region P of the recesses.

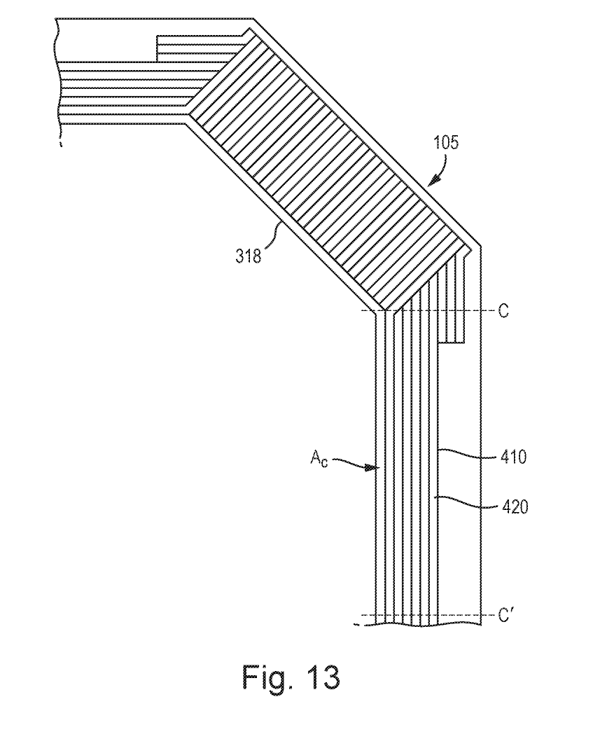

FIG. 12 illustrates a MEMS transducer structure according to a further example embodiment, and FIG. 13 shows an enlarged view of a portion of the structure shown in FIG. 12 according to a further example embodiment. Specifically, FIG. 12 shows a plan view of the upper surface of the substrate 105 which underlies the membrane layer 101. A projection of the unbound edges 310 of the active membrane which overlies the substrate are shown by the dotted lines. It will be seen that the first portion of the overlap region 400 which underlies an unbound edge of the active membrane extends between the second P′ and third P″ portions of the overlap region which underlie the support arms. These second and third overlap regions are located at the “corners” of the membrane layer which, in this example, exhibits a generally square or rectangular shape. The recesses 410 provided in the overlap region 400 do not intersect an edge of the cavity 318. It can also be seen that the longitudinal axis of the recesses, or channels, extends in a direction that is substantially parallel to the edge of the cavity. It will be appreciated that if the cavity were generally circular in shape, the longitudinal axis of the channels would extend in a direction parallel to a tangent of the edge of the cavity.

As a consequence of the recesses not intersecting the cavity edge 318, stress is more evenly distributed through the active membrane along the length of the unbound edge of the active membrane in the event that the membrane layer contacts the overlap region P of the substrate. Additionally, this configuration of recesses prevents points of high stress being produced in the membrane at the regions where the edge of the cavity contacts the membrane layer. The recesses 410 extend between the second and third portions of the overlap regions, and in this example embodiment, run substantially parallel to the edge of the substrate cavity. It should be appreciated that any dimension of recess 410 could be provided which is not perpendicular to the edge of the membrane layer.

For example, the recesses may be formed with a portion of the longitudinal axis extending generally in a direction between the second and third portions of the overlap regions. The recesses may have curved or straight portions, or a combination of both. Recesses which follow a curved path may substantially follow the path of the overlying unbound edge of the membrane. The curvature of the curved path of the recesses may increase from the cavity edge towards the perimeter of the membrane layer, or vice versa. Each recess may extend in a direction that is substantial parallel to the cavity, the perimeter of the active membrane region, the perimeter of the inactive membrane region, and/or the perimeter of the membrane layer. Each recess may be formed with a different geometry to the other recesses. The spacing between adjacent recesses may differ. Preferably, the recesses are arranged so that in the event that the active membrane contacts the substrate layer, the membrane will peel off the substrate in a direction substantially parallel to the recesses. Recesses may be arranged so as to intersect other recesses.

As can be seen from this Figure, recesses in the second and third portion of the overlap region P′, P″ may be provided so as to intersect the edge of the substrate cavity.

The location and area of the a first portion P of the upper surface of the substrate, i.e. a portion that is provided with at least one recess that does not intersect the cavity edge, can be beneficially selected according to the particular design of the transducer. Thus, for example, in the case of the circular membrane shape illustrated in FIGS. 7A-7C, it may be desirable for the first portion P to extend all the way around the cavity. Alternatively, the upper surface of the substrate may be provided with a plurality of discrete first portions which are disposed at intervals with respect to the edge of the cavity.

It will be appreciated that the depth and/or ratio between the width of the recess forming a lower region and the width of the adjacent ridges forming a high region, may be varied according to different examples. Furthermore, the profile or shape of the recesses may take a variety of forms. Thus it is envisaged that the recesses may be elliptical in shape.

The configuration of the recesses, for example in terms of the pitch, width and length, is a trade-off between obtaining adequately large impact area and preventing stiction. The membrane will react to incoming acoustic pressure waves by deflecting by an amount dependent on elastic restoring forces arising from the elasticity of the membrane. If the pressure is high enough then part of the membrane may make contact with an area, termed the impact area, of the underlying substrate at the periphery of the cavity in the substrate. On removal of the pressure, the membrane will tend to return to its equilibrium condition in response to the elastic restoring forces. However if the contact area is large enough, the membrane may remain attached to the substrate die due to stiction or similar effects. Adhesive forces will exert a certain force Fs per unit area of the contact area.

In the FIG. 11 example it will be appreciated that the active membrane 301 is suspended above the substrate and is under tension as a result of the bound edges.

The deflection of the active membrane will be greatest towards its centre. In the example shown in FIGS. 4 and 11, the centre of the unbound edge of the active membrane is furthest from any anchor point, or bound edge, and will be closest to the centre of the active membrane. Therefore, the initial point of contact of the active membrane in response to a sufficiently large deflection is likely to be at or near the centre of the unbound edge of the active membrane, followed by stiction of the unbound edge either side of the central region. Thus the direction of stiction of the unbound edge can be considered to extend from the centre of the unbound edge towards the adjacent bound edges.

The restoring forces acting on the membrane to restore the membrane to the equilibrium position will tend to result in the active membrane peeling away from the substrate in a direction that is substantially the opposite to the stiction direction, or a direction substantially towards the centre of the unbound edge.

It should be noted that at a region towards the centre of the unbound edge of the active membrane, the membrane will be under lower elastic tension when deflected than at regions closer to the bound edges of the active membrane. Therefore, in the overlap regions which extend between the regions underlying the support arms of the active membrane, restoring forces may be significantly lower and, thus, the risk of stiction in this region is higher. The direction of formation of the recesses, in particular the longitudinal axis of the recesses, is therefore an important consideration along regions underlying the unbound edges of the active membrane.

Thus, in the case of the substantially square-shaped membrane layer shown in FIGS. 4 and 11, it is particularly advantageous to provide a first substrate portion provided with recesses at a region disposed substantially centrally between the portions underlying the adjacent supporting arms of the flexible membrane, as this region may be the closest point to the centre of the flexible membrane. Thus, the unbound edge of the flexible membrane will deflect most mid-way between the adjacent bound edges, and is therefore more likely to contact the underlying substrate at or near this point. Thus, according to one or more examples, the first substrate portion P may be located only at a central region of the area between regions underlying the supporting arms.

The geometry and/or dimensions of the recesses may be selected such that Fs<Fr, wherein Fs is the adhesive force arising between the membrane and the substrate in use following a deflection of the membrane which causes the membrane and the substrate to come into contact, and Fr is the restoring force on the membrane that tends to restore the membrane to an equilibrium position.

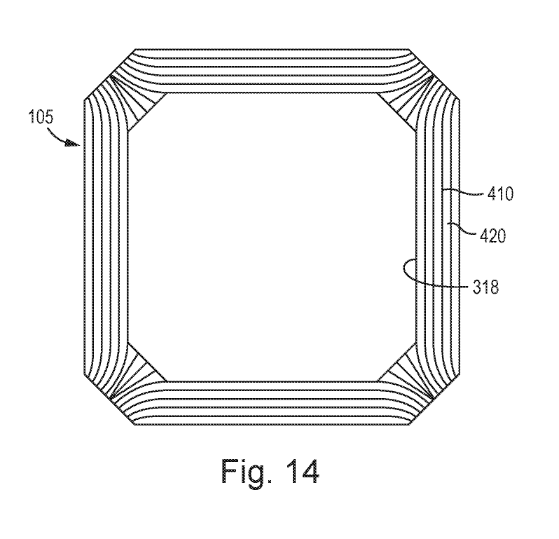

According to one or more examples arrangements are envisaged—such as is shown in FIG. 14—in which the channels or recesses 410 are designed to extend generally in the direction in which the membrane would peel from the substrate following contact with the substrate. Thus, the channels may follow a curved path which extends towards or terminates at the region underlying the adjacent bound edges of the active membrane.

According to one or more examples, at least one recess is provided having a longitudinal axis that is substantially parallel to the direction in which the active membrane will peel after contacting the substrate.

It is noted that references herein to the centre of a cavity are intended to refer to a centre of a plane across the cavity parallel to the undistorted membrane.

It should be understood that the various relative terms upper, lower, top, bottom, underside, overlying, beneath, etc. that are used in the present description should not be in any way construed as limiting to any particular orientation of the transducer during any fabrication step and/or it orientation in any package, or indeed the orientation of the package in any apparatus. Thus the relative terms shall be construed accordingly.

In the embodiments described herein, according to some examples the cavity comprises a though-hole through the substrate.

In some examples the periphery of the cavity comprises at least one convex and concave segment, and wherein the periphery of the through-hole has a circular or rectangular or pentagonal or octagonal shape.

In some examples the membrane is generally square or rectangular in shape, and wherein an active centre region of the membrane is under intrinsic stress.

In the embodiments described herein, a cross-section of the periphery of the cavity lies in a plane parallel to the surface of the substrate.

A MEMS transducer according to the embodiments described here may comprise a capacitive sensor, for example a microphone.

A MEMS transducer according to the embodiments described here may further comprise readout circuitry such as a low-noise amplifier, voltage reference and charge pump for providing higher-voltage bias, analogue-to-digital conversion or output digital interface or more complex analogue and/or digital processing or circuitry, or other components. There may thus be provided an integrated circuit comprising a MEMS transducer as described in any of the embodiments herein.

One or more MEMS transducers according to the embodiments described here may be located within a package. This package may comprise one or more sound ports. A MEMS transducer according to the embodiments described herein may be located within a package together with a separate integrated circuit comprising readout circuitry which may comprise analogue and/or digital circuitry such as a low-noise amplifier, voltage reference and charge pump for providing higher-voltage bias, analogue-to-digital conversion or output digital interface or more complex analogue or digital signal processing.

According to another aspect, there is provided an electronic device comprising a MEMS transducer according to any of the embodiments described herein. An electronic device may comprise, for example, at least one of: a portable device; a battery powered device; an audio device; a computing device; a communications device; a personal media player; a mobile telephone; a games device; and a voice controlled device.

According to another aspect, there is provided an integrated circuit comprising a MEMS transducer as described in any of the embodiments herein.

According to another aspect, there is provided a method of fabricating a MEMS transducer, wherein the MEMS transducer comprises a MEMS transducer as described in any of the embodiments herein.

Furthermore, in the embodiments described herein, it will be appreciated that a transducer may comprise other components, for example electrodes, or a backplate structure, wherein the flexible membrane layer is supported with respect to said backplate structure. The backplate structure may comprises a plurality of holes through the backplate structure.

Although the various embodiments describe a MEMS capacitive microphone, the invention is also applicable to any form of MEMS transducers other than microphones, for example pressure sensors or ultrasonic transmitters/receivers.

Embodiments of the invention may be usefully implemented in a range of different material systems, however the embodiments described herein are particularly advantageous for MEMS transducers having membrane layers comprising silicon nitride.

The MEMS transducer may be formed on a transducer die and may in some instances be integrated with at least some electronics for operation of the transducer.

In the embodiments described above it is noted that references to a transducer element may comprise various forms of transducer element. For example, a transducer element may comprise a single membrane and back-plate combination. In another example a transducer element comprises a plurality of individual transducers, for example multiple membrane/back-plate combinations. The individual transducers of a transducer element may be similar, or configured differently such that they respond to acoustic signals differently, e.g. the elements may have different sensitivities. A transducer element may also comprises different individual transducers positioned to receive acoustic signals from different acoustic channels.

It is noted that in the embodiments described herein a transducer element may comprise, for example, a microphone device comprising one or more membranes with electrodes for read-out/drive deposited on the membranes and/or a substrate or back-plate. In the case of MEMS pressure sensors and microphones, the electrical output signal may be obtained by measuring a signal related to the capacitance between the electrodes. However, it is noted that the embodiments are also intended to embrace the output signal being derived by monitoring piezo-resistive or piezo-electric elements or indeed a light source. The embodiments are also intended embrace a transducer element being a capacitive output transducer, wherein a membrane is moved by electrostatic forces generated by varying a potential difference applied across the electrodes, including examples of output transducers where piezo-electric elements are manufactured using MEMS techniques and stimulated to cause motion in flexible members.

It is noted that the embodiments described above may be used in a range of devices, including, but not limited to: analogue microphones, digital microphones, pressure sensor or ultrasonic transducers. The invention may also be used in a number of applications, including, but not limited to, consumer applications, medical applications, industrial applications and automotive applications. For example, typical consumer applications include portable audio players, wearable devices, laptops, mobile phones, PDAs and personal computers. Embodiments may also be used in voice activated or voice controlled devices. Typical medical applications include hearing aids. Typical industrial applications include active noise cancellation. Typical automotive applications include hands-free sets, acoustic crash sensors and active noise cancellation.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

1. A MEMS transducer comprising:
a membrane comprising an active membrane region;
a substrate having a cavity;
wherein an upper surface of the substrate comprises an overlap region which underlies the membrane, wherein a first portion of the overlap region is provided with at least one recess, and wherein the at least one recess does not intersect an edge of the cavity.

2. A MEMS transducer as claimed in claim 1 wherein the active membrane region comprises a plurality of bound edges and a plurality of unbound edges.

3. A MEMS transducer as claimed in claim 1 wherein the active membrane region comprises a central region and a plurality of support arms which extend laterally from the central region.

4. A MEMS transducer as claimed in claim 2, wherein the first portion of the overlap region underlies a first unbound edge of the active membrane.

5. A MEMS transducer as claimed in claim 1 wherein the first portion of the overlap region is provided between a second portion of the overlap region and a third portion of the overlap region.

6. A MEMS transducer as claimed in claim 5 wherein the second and third portions of the overlap region each underlie one of the plurality of support arms of the membrane.

7. A MEMS transducer as claimed in claim 5 wherein the at least one recess is disposed between the second and third portion of the overlap region.

8. A MEMS transducer as claimed in claim 5 wherein at least a portion of the at least one recess extends between the second portion of the overlap region and the third portion of the overlap region.

9. A MEMS transducer as claimed in claim 1, wherein at least one recess is provided having a longitudinal axis that is substantially parallel to the direction in which the active membrane will peel after contacting the substrate.

10. A MEMS transducer as claimed in claim 1, wherein the recess comprises a lower region which is provided between adjacent higher regions in the upper surface of the substrate.

11. A MEMS transducer as claimed in claim 1, wherein the recess comprises a channel formed in the upper surface of the substrate.

12. A MEMS transducer as claimed in claim 11 wherein the channel is generally longitudinal and comprises a longitudinal axis.

13. A MEMS transducer as claimed in claim 12, wherein at least a portion of the longitudinal axis of the channel extends in a direction that is substantially parallel to the edge of the substrate cavity.

14. A MEMS transducer as claimed in claim 12, wherein at least a portion of the longitudinal axis of the channel extends in a direction that is substantially parallel to an unbound edge of the active membrane.

15. A MEMS transducer as claimed in claim 12, wherein at least a portion of the longitudinal axis of the channel extends in a direction that is substantially parallel to a perimeter of the membrane.

16. A MEMS transducer as claimed in claim 12, wherein the longitudinal axis of the channel does not intersect the edge of the cavity.

17.-23. (canceled)

24. A MEMS transducer comprising a substrate, the substrate comprising a cavity which extends through the substrate from an upper surface of the substrate to a lower surface of the substrate wherein the upper surface of the substrate is provided with at least one longitudinal channel, wherein a longitudinal axis of the at least one channel extends in a direction parallel to a notional line drawn tangentially to an edge of the cavity.

25. A MEMS transducer comprising:
a membrane, the membrane being provided with at least one slit which defines a flexible portion of the membrane;
a substrate having a cavity;
wherein the membrane overlies the substrate and wherein at least one recess is formed in an upper surface of the substrate which underlies the at least one slit.

26. A MEMS transducer as claimed in claim 1, wherein the geometry and/or dimensions of the recesses are selected such that Fs<Fr, wherein Fs is the adhesive force arising between the membrane and the substrate in use following a deflection of the membrane which causes the membrane and the substrate to come into contact, and Fr is the restoring force on the membrane that tends to restore the membrane to an equilibrium position.

27. (canceled)

28. An electronic device comprising a MEMS transducer as claimed in claim 1.

29.-36. (canceled)
